(19) United States
(12) Patent Application Publication
(10) Pub. No.: US 2014/0332072 A1
(43) Pub. Date: Nov. 13, 2014

(54) Photovoltaic Cell And Method Of Forming The Same

(71) Applicants: Dow Corning Corporation, Midland, MI (US); IMEC, Leuven,BE (BE)

(72) Inventors: Guy Damien Serge Beaucarne, Oud-heverlee (BE); Jorg (or Joerg) Horzel, Heverlee (BE); Nicholas E. Powell, Midland, MI (US); Loic Tous, Leuven (BE); Donald Adriaan Wood, Arquennes (BE); Adriana Petkova Zambova, Midland, MI (US)

(21) Appl. No.: 14/364,819

(22) PCT Filed: Dec. 13, 2012
(86) PCT No.: PCT/US2012/069492

§ 371 Date: Jun. 12, 2014

Related U.S. Application Data
(60) Provisional application No. 61/569,992, filed on Dec. 13, 2011.

(51) Int. Cl. H01L 31/02; H01L 31/0224; H01L 31/18

(52) U.S. Cl. CPC H01L 31/0201; H01L 31/18; H01L 31/022433
USPC 136/256; 438/98

(57) ABSTRACT

A photovoltaic (PV) cell comprises a base substrate comprising silicon and including an upper doped region. A coating layer is disposed on the upper doped region and has an outer surface. Fingers are disposed in the coating layer. Each finger has a lower portion in electrical contact with the upper doped region, and an upper portion extending outwardly through the outer surface. Each finger comprises a first metal. A busbar is spaced from the upper doped region, which is free of physical contact with the busbar. The busbar is in electrical contact with the upper portions of the fingers. The busbar comprises a second metal and a third metal different from the first and second metals. The third metal has a melting temperature of no greater than about 300° C. A method of forming the PV cell is also provided.

### CROSS REFERENCE TO RELATED APPLICATIONS

This application claims the benefit of U.S. Provisional Patent Application Ser. No. 61/569,992, filed on Dec. 13, 2011, which is incorporated herewith by reference in its entirety.

### FIELD OF THE INVENTION

The present invention generally relates to a photovoltaic (PV) cell and to a method of forming the PV cell.

### BACKGROUND

Front surface metallization is an important aspect of photovoltaic (PV) cells which allows for collection and transport of charge carriers to busbars. The metallization is generally in the form of a grid, which includes narrow lines or “fingers” of conductive material which connect to wider busbars. Tabbing, e.g. ribbon, is soldered to the busbars to connect multiple PV cells together (e.g. in series). Typically, the grid is formed using pastes which include silver (Ag) as a primary component due to its excellent conductivity. Unfortunately, such metallization makes up a substantial portion of overall manufacturing cost due to reliance on Ag being present in both the fingers and busbars of the PV cells. As such, there remains an opportunity to provide improved PV cells and methods of forming the same.

### SUMMARY OF THE INVENTION

The present invention provides a photovoltaic (PV) cell. The PV cell comprises a base substrate comprising silicon and includes an upper doped region. A coating layer is disposed on the upper doped region of the base substrate and has an outer surface. A plurality of fingers spaced from each other is disposed in the coating layer. Each of the fingers has a lower portion in electrical contact with the upper doped region of the base substrate. Each of the fingers also has an upper portion opposite the lower portion extending outwardly through the outer surface of the coating layer. Each of the fingers comprises a first metal, which is present in each of the fingers in a majority amount. A busbar is spaced from the upper doped region of the base substrate. The upper doped region of the base substrate is free of physical contact with the busbar. The busbar is in electrical contact with the upper portions of the fingers. The busbar comprises a second metal present in the busbar in a majority amount. The busbar further comprises a third metal different from the first metal of the fingers and the second metal of the busbar. The third metal has a melting temperature of no greater than about 300° C. The upper doped region of the base substrate is in electrical communication with the busbar via the fingers.

The present invention also provides a method of forming the invention PV cell. The method comprises the step of applying a composition to at least a portion of the upper portions of the fingers to form a layer. The upper doped region of the base substrate is free of physical contact with the layer formed by the composition. The second metal is present in the composition in a majority amount. The third metal is also present in the composition.

The method further comprises the step of heating the layer to a temperature no greater than about 300° C. to form the busbar. The upper doped region of the base substrate is in electrical communication with the busbar via the fingers. The invention PV cell may be used for converting light of many different wavelengths into electricity.

### BRIEF DESCRIPTION OF THE DRAWINGS

The present invention may be readily appreciated, as the same becomes better understood by reference to the following detailed description when considered in connection with the accompanying drawings wherein:

FIG. 1 is a front view of an embodiment of the PV cell including a base substrate, a coating layer, fingers, and a pair of busbars;

FIG. 2 is a partial cross-sectional side view taken along line 2-2 of FIG. 1 illustrating an upper doped region of the base substrate, the coating layer, fingers, and one of the busbars;

FIG. 3 is a cross-sectional side view of an embodiment of the PV cell illustrating upper and lower doped regions of a base substrate, a coating layer, fingers, a busbar, and an electrode;

FIG. 4 is a partial cross-sectional perspective view of an embodiment of the PV cell illustrating an upper doped region of a base substrate, a coating layer, fingers, and a pair of busbars;

FIG. 5 is a partial cross-sectional perspective view of another embodiment of the PV cell illustrating an upper doped region of a base substrate, a textured surface, a coating layer, and a pair of fingers extending into the base substrate;

FIG. 6 is a flow chart illustrating steps of an embodiment of the method of forming the PV cell;

FIG. 7 is a flow chart illustrating steps of another embodiment of the method of forming another embodiment of the PV cell;

FIG. 8 is a diagram illustrating polymer curing and solder flow of a composition useful for forming the busbars of the PV cell;

FIG. 9 is a partial cross-sectional perspective view of another embodiment of the PV cell illustrating an upper doped region of a base substrate, a coating layer, fingers, a pair of busbars, and a pair of tabbing ribbons with one of the tabbing ribbons being disposed on one of the busbars;

FIG. 10 is a schematic front view of an embodiment of the PV cell including a passivation layer, discontinuous-fingers, and a busbar;

FIG. 11 is a schematic front view of an embodiment of the PV cell including a passivation layer, discontinuous-fingers, supplemental fingers, and a busbar;

FIG. 12 is a schematic front view of an embodiment of the PV cell including a passivation layer, fingers, a busbar, and supplemental busbar pads;

FIG. 13 is a schematic front view of an embodiment of the PV cell including a passivation layer, fingers, a pair of busbars, and a supplemental busbar;

FIG. 14 is a schematic front view of an embodiment of the PV cell including a passivation layer, fingers having pads, and a busbar;

FIG. 15 is a schematic front view of an embodiment of the PV cell including a passivation layer, fingers having hollow pads, and a busbar;

FIG. 16 is a schematic front view of an embodiment of the PV cell including a passivation layer, discontinuous-fingers, supplemental fingers, and a busbar;

FIG. 17 is a box graph illustrating short-circuit current density (J_{SC}) of comparative and invention examples;

FIG. 18 is a box graph illustrating open-circuit voltage (V_{OC}) of comparative and invention examples;

FIG. 19 is a box graph illustrating cell efficiency (NCell) of comparative and invention examples

FIG. 20 is a box graph illustrating efficiency percentage of comparative and invention examples;

FIG. 21 is another box graph illustrating J_{SC} of comparative and invention examples;

FIG. 22 is another box graph illustrating V_{OC} of comparative and invention examples;

FIG. 23 is a cross-sectional optical microscopy photograph (converted to drawing form) illustrating a tabbed busbar of the invention, a finger, and a passivation layer;

FIG. 24 is a line graph illustrating J_{SC} of comparative and invention examples after damp heat aging;

FIG. 25 is a line graph illustrating V_{OC} of comparative and invention examples after damp heat aging; and

FIG. 26 is a line graph illustrating sheet resistivity (rs) of comparative and invention examples after damp heat aging.

### DETAILED DESCRIPTION OF THE INVENTION

Referring to the Figures, wherein like numerals indicate like parts throughout the several views, an embodiment of the photovoltaic (PV) cell is generally shown at 20. PV cells 20 are useful for converting light of many different wavelengths into electricity. As such, the PV cell 20 can be used for a variety of applications. For example, a plurality of PV cells 20 can be used in a solar module (not shown). The solar module can be used in a variety of locations and for a variety of applications, such as in residential, commercial, or industrial, applications. For example, the solar module can be used to generate electricity, which can be used to power electrical devices (e.g. lights and electric motors), or the solar module can be used to shield objects from sunlight (e.g. shield automobiles parked under solar modules that are disposed over parking spaces). The PV cell 20 is not limited to any particular type of use. The figures are not drawn to scale. As such, certain components of the PV cell 20 may be larger or smaller than as depicted.

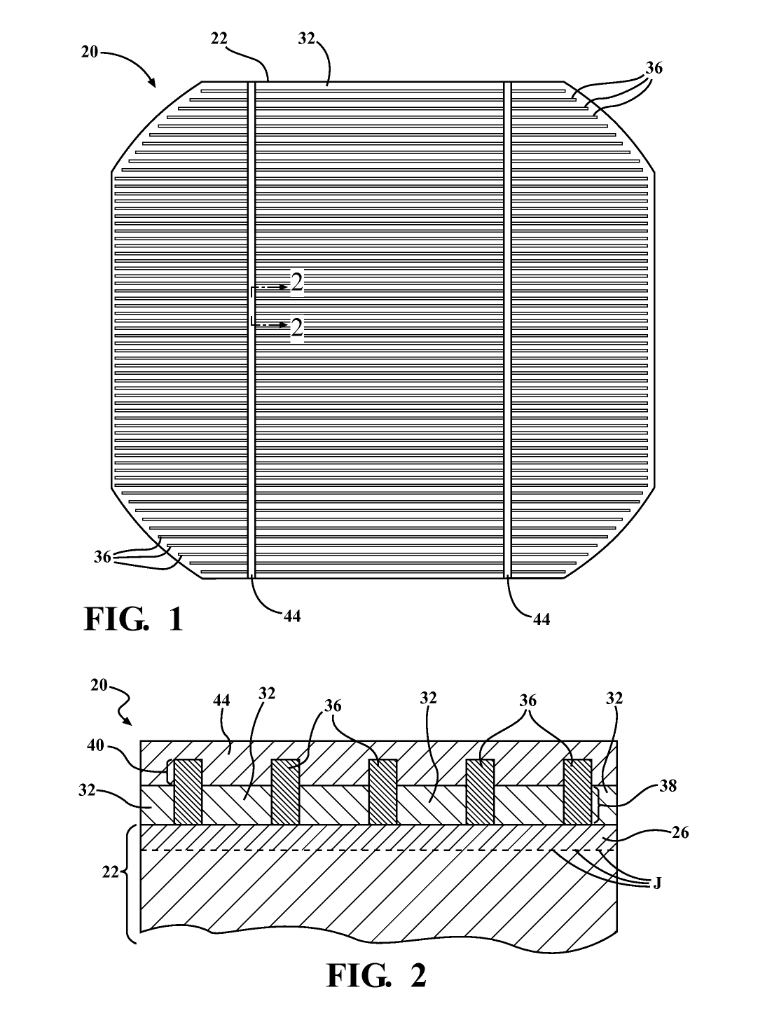

Referring to FIG. 1, the PV cell 20 is shown in a square configuration with rounded corners, i.e., a pseudo-square. While this configuration is shown, the PV cell 20 may be configured into various shapes. For example, the PV cell 20 may be a rectangle with corners, a rectangle with rounded or curved corners, a circle, etc. The PV cell 20 is not limited to any particular shape. The PV cell 20 can be of various sizes, such as 4 by 4 inch (10.2 by 10.2 cm) squares, 5 by 5 inch (12.7 by 12.7 cm) squares, 6 by 6 inch (15.2 by 15.2 cm) squares, etc. The PV cell 20 is not limited to any particular size.

Referring to FIG. 2, the PV cell 20 comprises a base substrate 22. The base substrate 22 comprises silicon. The silicon may also be referred to in the art as a semiconductor material. Various types of silicon can be utilized, such as monocrystalline silicon, polycrystalline silicon, amorphous silicon, or combinations thereof. In certain embodiments, the base substrate 22 comprises crystalline silicon, e.g. monocrystalline silicon. The PV cell 20 is generally referred to in the art as a wafer type PV cell 20. Wafers are thin sheets of silicon that are typically formed from mechanically sawing the wafer from a single (mono) crystal or multicrystal silicon ingot. Alternatively, wafers can be formed from casting silicon, from epitaxial liftoff techniques, pulling a silicon sheet from a silicon melt, etc.

The base substrate 22 is generally planar, but may also be non-planar. The base substrate 22 can include a textured surface 24. The textured surface 24 is useful for reducing reflectivity of the PV cell 20. The textured surface 24 may be of various configurations, such as pyramidal, inverse pyramidal, random pyramidal, isotropic, etc. An example of texturing is illustrated in FIG. 5. Texturing can be imparted to the base substrate 22 by various methods. For example, an etching solution can be used for texturing the base substrate 22. The PV cell 20 is not limited to any particular type of texturing process. The base substrate 22, e.g. wafer, can be of various thicknesses, such as from about 1 to about 1000, about 75 to about 750, about 75 to about 300, about 100 to about 300, or about 150 to about 200, μm thick on average.

The base substrate 22 is typically classified as a p-type or an n-type, silicon substrate (based on doping). The base substrate 22 includes an upper (or front side) doped region 26, which is generally the sun up/facing side. The upper doped region 26 may also be referred to in the art as a surface emitter, or active semiconductor, layer. In certain embodiments, the upper doped region 26 of the base substrate 22 is an n-type doped region 26 (e.g. an n⁺ emitter layer) such that a remainder of the base substrate 22 is generally p-type. In other embodiments, the upper doped region 26 of the base substrate 22 is a p-type doped region 26 (e.g. a p⁺ emitter layer) such that a remainder of the base substrate 22 is generally n-type. The upper doped region 26 can be of various thicknesses, such as from about 0.1 to about 5, about 0.3 to about 3, or about 0.4, μm thick on average. The upper doped region 26 may be applied such that doping under the fingers 36 (described below) is increased, such as in “selective emitter” technologies.

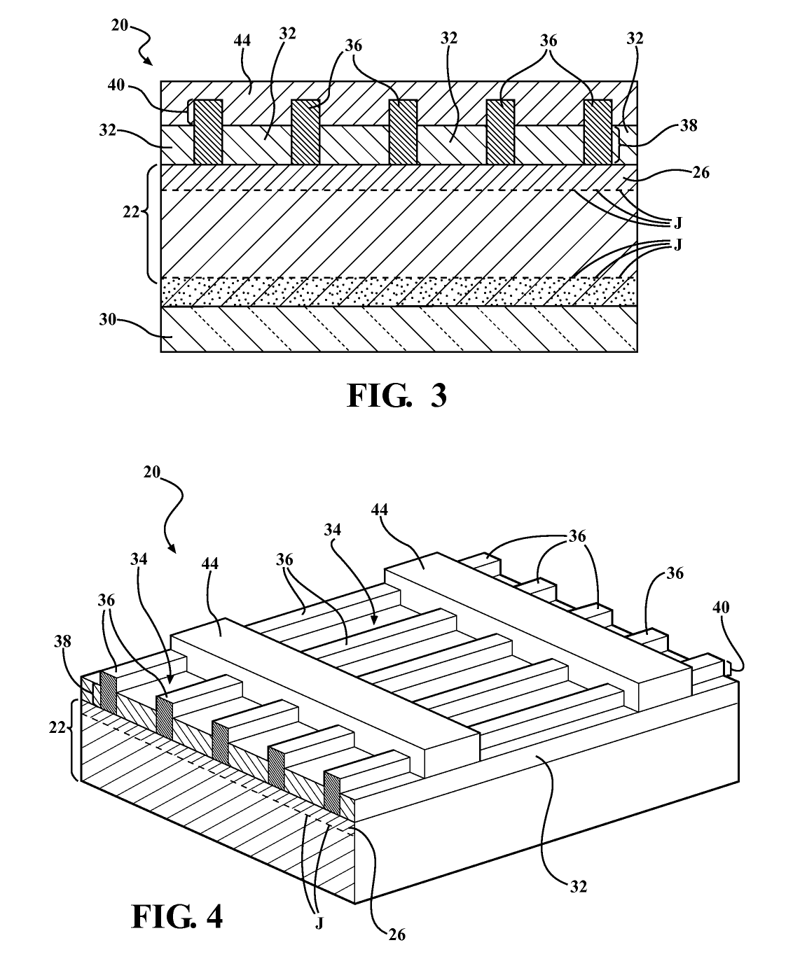

Referring to FIG. 3, the base substrate 22 typically includes a lower doped region 28 opposite the upper doped region 26. The lower doped region 28 may also be referred to in the art as a back surface field (BSF). Typically, one of the doped regions, e.g. the upper 26, is an n-type and the other doped region, e.g. the lower 28, is a p-type. The opposite arrangement may also be used, i.e., the upper 26 is a p-type and the lower 28, is an n-type. Such configurations, where the oppositely doped region 26,28 interfaces, are referred to in the art as p-n junctions (J) and are useful for photo-excited charge separation provided there is at least one positive (p) region and one negative (n) region. Specifically, when two regions of different doping are adjacent, a boundary defined there between is generally referred to in the art as a junction. When the doping are of opposite polarities then the junction (J) is generally referred to as a p-n junction (J). When doping is merely of different concentrations, the “boundary” may be referred to as an interface, such as an interface between like regions, e.g. p and p⁺ regions. As shown generally in the Figures, such junctions (J) may be optional, depending on what type of doping is utilized in the base substrate 22. The PV cell 20 is not limited to any particular number or location of junction(s) (J). For example, the PV cell 20 may only include only one junction (J), at the front or rear.

Various types of dopants and doping methods can be utilized to form the doped regions 26,28 of the base substrate 22. For example, a diffusion furnace can be used to form an n-type doped region 26,28 and a resulting n-p (or “p-n”) junction (J). An example of a suitable gas is phosphoryl chloride (POCl₃). In addition or alternate to phosphorus, arsenic can also be used to form n-type regions 26,28. At least one of the periodic table elements from group V, e.g. boron or gallium, can be used to form p-type regions 26,28. The PV cell 20 is not limited to any particular type of dopant or doping process.

Doping of the base substrate 22 can be at various concentrations. For example, the base substrate 22 can be doped at different dopant concentrations to achieve resistivity of from about 0.5 to about 10, about 0.75 to about 3, or about 1, Ω·cm (Ω·cm). The upper doped region 26 can be doped at different dopant concentrations to achieve sheet resistivity of from about 50 to about 150, or about 75 to about 125, or about 100, Q/□ (Ω per square). In general, a higher concentration of doping may lead to a higher open-circuit voltage (V_{OC}) and lower resistance, but higher concentrations of doping can also result in charge recombination depleting cell performance and introduce defect regions in the crystal.

Typically, there is an electrode 30 disposed on the lower doped region 28, opposite the upper doped region 26. The electrode 30 may cover the entire lower doped region 28 or only a portion thereof. If the later, typically a passivation layer (not shown), e.g. a layer of SiN_{X}, is used to protect exposed portions of the lower doped region 28, but the passivation layer is not used between the electrode 30 and the portion of lower doped region 28 in direct physical and electrical contact. The electrode 30 may take the form of a layer, a layer having localized contacts, or a contact grid comprising fingers and busbars. Examples of suitable configurations include p-type base configurations, n-type base configurations, PERC or PERL type configurations, bifacial BSF type configurations, heterojunction with intrinsic thin layer (HIT) configurations, etc. The PV cell 20 is not limited to any particular type of electrode 30 or electrode configuration. Some of these embodiments, as well as others, are described in detail below.

In embodiments where the lower doped region 28 is a p-type, the electrode 30 typically comprises at least one of the periodic table elements of group III, e.g. aluminum (Al). Al can be used as a p-type dopant. For example, an Al paste can be applied to the base substrate 22 and then fired to form the electrode 30, while also forming the lower p⁺ -type doped region 28. The Al paste can be applied by various methods, such as by a screen printing process. Other suitable methods are described below.

As best shown in FIGS. 2 and 3, a coating layer 32 is disposed on the upper doped region 26. The coating layer 32 is useful for increasing sunlight absorption by the PV cell 20, e.g. by reducing reflectivity of the PV cell 20, as well as generally improving wafer lifetime through surface and bulk passivation. The coating layer 32 has an outer surface 34 opposite the upper doped region 26. The coating layer 32 may also be referred to in the art as a dielectric passivation, or anti-reflective coating (ARC), layer.

The coating layer 32 may be formed from various materials. In certain embodiments, the coating layer 32 comprises SiO_{X}, ZnS, MgF_{X}, SiN_{X}, SiCN_{X}, AlO_{X}, TiO₂, a transparent conducting oxide (TCO), or combinations thereof. Examples of suitable TCOs include doped metal oxides, such as tin-doped indium oxide (ITO), aluminum-doped zinc-oxide (AZO), indium-doped cadmium-oxide, fluorine-doped tin oxide (FTO), or combinations thereof. In certain embodiments, the coating layer 32 comprises SiN_{X}. Employing SiN_{X} is useful due to its excellent surface passivation qualities. Silicon nitride is also useful for preventing carrier recombination at the surface of the PV cell 20.

The coating layer 32 may be formed from two or more sub-layers (not shown), such that the coating layer 32 may also be referred to as a stack. Such sub-layers can include a bottom ARC (B-ARC) layer and/or a top ARC (T-ARC) layer. Such sub-layers can also be referred to as dielectric layers, and be formed from the same or different material. For example, there may be two or more sub-layers of SiN_{X}; a sub-layer of SiN_{X} and a sub-layer of AlO_{X}; etc.

The coating layer 32 can be formed by various methods. For example, the coating layer 32 can be formed by using a plasma-enhanced chemical vapor deposition (PECVD) process. In embodiments where the coating layer 32 comprises SiN_{X}, silane, ammonia, and/or other precursors can be used in a PECVD furnace to form the coating layer 32. The coating layer 32 can be of various thicknesses, such as from about 10 to about 150, about 50 to about 90, or about 70, nm thick on average. Sufficient thickness can be determined by the refractive indices of the coating material and base substrate 22. The PV cell 20 is not limited to any particular type of coating process.

A plurality of fingers 36 are spaced from each other and disposed in the coating layer 32. Each of the fingers 36 has a lower portion 38 in electrical contact with the upper doped region 26 of the base substrate 22. The lower portion 38 in actual electrical contact may be quite small, such as tips/ends of the fingers 36. Each of the fingers 36 also has an upper portion 40 opposite the lower portion 38 extending outwardly through the outer surface 34 of the coating layer 32. The fingers 36 are generally disposed in a grid pattern, as best shown in FIGS. 1 and 4. Typically, the fingers 36 are disposed such that the fingers 36 are relatively narrow while being thick enough to minimize resistive losses. Orientation and number of the fingers 36 may vary.

As shown in FIG. 5, in certain embodiments, the fingers 36 extend downwardly into the base substrate 22. Such configurations may be referred to in the art as “buried contact cells”. Grooves can be formed into the base substrate 22 by lasers such that the PV cell 20 may be referred to in the art as a laser grooved buried grid (LGBG) PV cell 20. Typically, such PV cells 20 include local “selective emitter” layers 42 around the grooves, such as n⁺⁺ emitter layers. Other methods can also be used to form the grooves besides lasers, such as sawing, etching, etc.

The fingers 36 can be of various widths, such as from about 10 to about 200, about 70 to about 150, about 90 to about 120, or about 100, μm wide on average. The fingers 36 can be spaced various distances apart from each other, such as from about 1 to about 5, about 2 to about 4, or about 2.5, mm apart on average. The fingers 36 can be of various thicknesses, such as from about 5 to about 50, about 5 to about 25, or about 10 to about 20, μm thick on average.

Each of the fingers 36 comprises a first metal, which is present in each of the fingers 36 in a majority amount. The first metal may comprise various types of metals. In certain embodiments, the first metal comprises silver (Ag). In other embodiments, the first metal comprises copper (Cu). By “majority amount”, it is generally meant that the first metal is the primary component of the fingers 36, such that it is present in an amount greater than any other component that may also be present in the fingers 36. In certain embodiments, such a majority amount of the first metal, e.g. Ag, is generally greater than about 35, greater than about 45, or greater than about 50, weight percent (wt %), each based on the total weight of the finger 36.

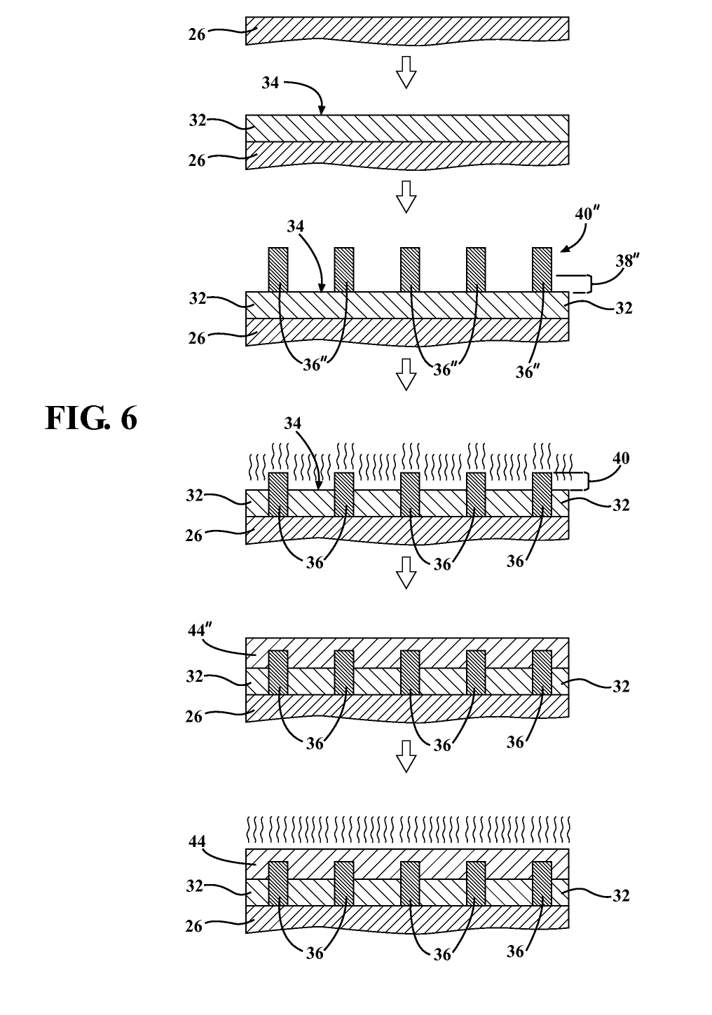

The fingers 36 can be formed by various methods. Suitable methods include sputtering; vapor deposition; strip or patch coating; ink-jet printing, screen printing, gravure printing, letter printing, thermal printing, dispensing or transfer printing; stamping; electroplating; electroless plating; or combinations thereof. One type of method is generally referred to as an etching/firing process, is described below and illustrated in FIG. 6. Suitable compositions for forming the fingers 36 are described further below.

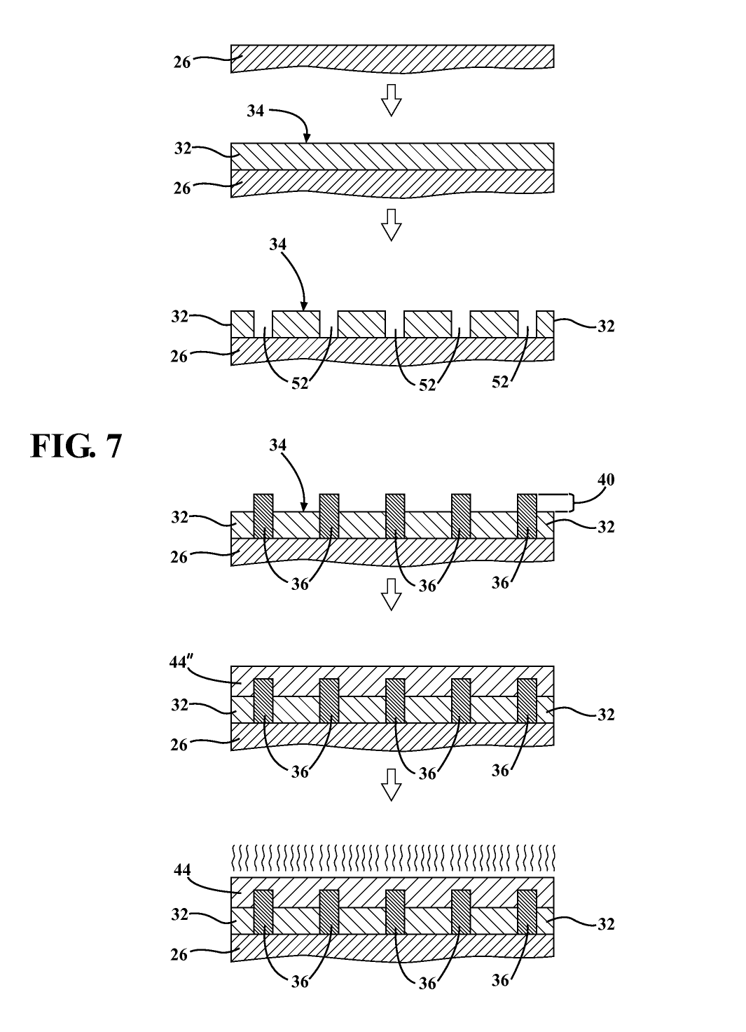

In certain embodiments, the fingers 36 are formed by a plating process (rather than an etching/firing process). In these embodiments, the fingers 36 generally comprise a plated or stacked structure (not shown). For example, the fingers 36 can comprise two or more of the following layers: nickel (Ni), Ag, Cu, and/or tin (Sn). The layers can be in various orders, provided the Cu layer (if present) is not in direct physical contact with the upper doped region 26 of the base substrate 22. Typically, a seed layer comprising Ag or a metal other than Cu, e.g. Ni, is in contact with the upper doped region 26. In certain embodiments, the seed layer comprises Ni silicide. Subsequent layers are then disposed on the seed layer to form the fingers 36. When the fingers 36 include Cu, a passivation layer such as Sn or Ag is disposed over the Cu layer to prevent oxidation. In certain embodiments, the lower portions 38 of the fingers 36 comprise Ni, the upper portions 40 of the fingers 36 comprise Sn, and Cu is disposed between the Ni and Sn. In this way, the Cu is protected from oxidation by the Ni, Sn, and surrounding coating layer 32. Such layers can be formed by various methods, such as aerosol printing and firing; electrochemical deposition; etc. One method is described below and illustrated in FIG. 7. The PV cell 20 is not limited to any particular type of process of forming the fingers 36.

A busbar 44 is spaced from the upper doped region 26 of the base substrate 22. As shown in FIGS. 1 and 4, the PV cell 20 generally has two busbars 44. In certain embodiments, the PV cell 20 may have more than two busbars 44 (not shown), such as three busbars 44, four busbars 44, six busbars 44, etc. Each busbar 44 is in electrical contact with the upper portions 40 of the fingers 36. The busbars 44 are useful for collecting current from the fingers 36 which have collected current from the upper doped region 26. As best shown in FIG. 4, each of the busbars 44 is disposed on the outer surface 34 of the coating layer 32 and around each of the fingers 36 to provide intimate physical and electrical contact to the upper portions 40 of the fingers 36. Typically, the busbar 44 is transverse the fingers 36. Said another way, the busbar 44 can be at various angles relative to the fingers 36, including perpendicular. The upper portion 40 in actual physical/electrical contact may be small, such as just tips/ends of the fingers 36. Such contact places the busbar 44 in position for carrying current directly from the fingers 36. The fingers 36 themselves are in intimate physical and electrical contact with the upper doped region 26 of the base substrate 22.

The busbar 44 can be of various widths, such as from about 0.5 to about 10, about 1 to about 5, or about 2, mm wide on average. The busbar 44 can be of various thicknesses, such as from about 0.1 to about 500, about 10 to about 250, about 30 to about 100, or about 30 to about 50, μm thick on average. The busbars 44 can be spaced various distances apart. Typically, the busbars 44 are spaced to divide lengths of the fingers 36 into ˜equal regions, e.g. as shown in FIG. 1.

The busbar 44 comprises a second metal, which is present in the busbar 44 in a majority amount. The “second” is used to differentiate the metal of the busbar 44 from the “first” metal of the fingers 36, and does not imply quantity or order. The second metal may comprise various types of metals. In certain embodiments, the second metal of the busbar 44 is the same as the first metal of the fingers 36. For example, both the first and second metals can be Cu. In other embodiments, the second metal of the busbar 44 is different from the first metal of the fingers 36. In these embodiments, the first metal typically comprises Ag and the second metal typically comprises Cu. In other embodiments, the second metal comprises Ag. By “majority amount”, it is generally meant that the second metal is the primary component of the busbar 44, such that it is present in an amount greater than any other component that may also be present in the busbar 44. In certain embodiments, such a majority amount of the second metal, e.g. Cu, is generally greater than about 25, greater than about 30, greater than about 35, or greater than about 40, wt %, each based on the total weight of the busbar 44.

The busbar 44 also generally comprises a third metal. The third metal is different from the first metal of the fingers 36. The third metal is also different from the second metal of the busbar 44. Typically, the metals are different elements, rather than just different oxidation states of the same metal. The “third” is used to differentiate the metal of the busbar 44 from the “first” metal of the fingers 36, and does not imply quantity or order. The third metal melts at a lower temperature than melting temperatures of the first ands second metals. Typically, the third metal has a melting temperature of no greater than about 300, no greater than about 275, or no greater than about 250, ° C. Such temperatures are useful for forming the busbar 44 at low temperatures as described further below.

In certain embodiments, the third metal comprises solder. The solder can comprise various metals or alloys thereof. One of these metals is typically Sn, lead, bismuth, cadmium, zinc, gallium, indium, tellurium, mercury, thallium, antimony, Ag, selenium, and/or an alloy of two or more of these metals. In certain embodiments, the solder comprises a Sn alloy, such as a eutectic alloy, e.g. Sn63/Pb37. In certain embodiments, the solder powder comprises two different alloys, such as a Sn alloy and a Ag alloy, alternatively more than two different alloys. The third metal can be present in the busbar 44 in various amounts, typically in an amount less than the second metal. The busbar 44 typically comprises at least one a polymer in addition to the second and third metals, as described further below.

As best shown in FIG. 4, the upper doped region 26 of the base substrate 22 is free of (direct) physical contact with the busbar 44. Specifically, the coating layer 32 serves as a “barrier” between the busbar 44 and upper doped region 26. Without being bound or limited by any particular theory, it is believed that physical separation of the busbar 44 and the upper doped region 26 is beneficial for at least two reasons. First, such separation prevents diffusion of the second metal, e.g. Cu, into the upper doped region 26. It is believed that preventing such diffusion prevents the upper doped region 26, e.g. the p-n junction (J), from being shunted by the second metal of the busbar 44. Second, such physical separation is believed to reduce minority carrier recombination at the metal and silicon interfaces. It is believed that by reducing the area of metal/silicon interface, loss due to recombination is generally reduced and open-circuit voltage (V_{OC}) and short-circuit current density (J_{SC}) are generally improved. The area is reduced due to the coating layer 32 being disposed between much of the busbar 44 and the upper doped region 26, with the fingers 36 being the only metal components in contact with the upper doped region 26 of the base substrate 22. Additional embodiments of the PV cell 20 will now be described immediately below.

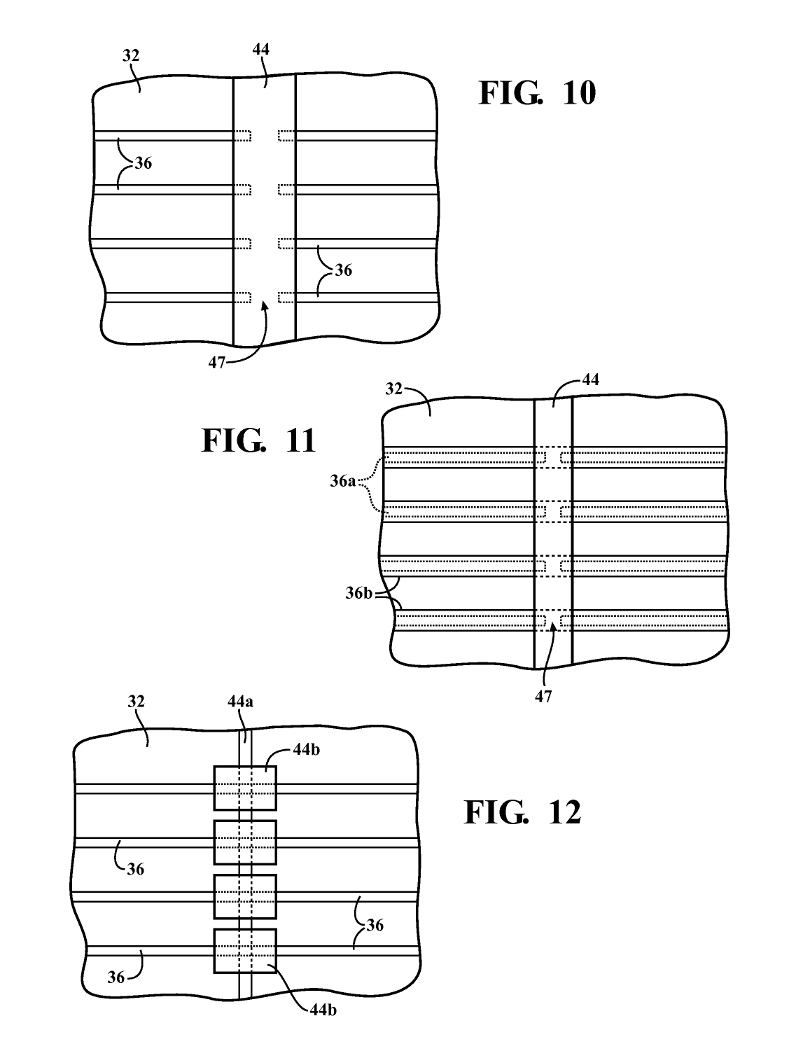

The PV cell 20 of FIG. 10 is similar to that of FIG. 1, but includes discontinuous-fingers 36. The busbar 44 is disposed over a gap 47 defined between the fingers 36. The gap 47 can be of various widths, provided the busbar 44 is in electrical contact with the fingers 36. The fingers 36 may comprise a majority of one metal, e.g. Ag, whereas the busbar 44 another metal, e.g. Cu. By having gaps 47, cost of manufacture can be reduced (such as by reducing the total amount of Ag utilized), and/or adhesion may be positively impacted.

The PV cell 20 of FIG. 11 is similar to that of FIG. 10, but further includes supplemental fingers 36b disposed over the fingers 36a. The supplemental fingers 36b may comprise the same material as the busbar 44, e.g. Cu, or a different material. The supplemental fingers 36b and the busbar 44 may be separate (e.g. one lying over the other) or unitary. By utilizing the supplemental fingers 36b, the size of the fingers 36a (e.g. Ag fingers) can be reduced, which can reduce cost of manufacture and/or improve adhesion.

The PV cell 20 of FIG. 12 includes fingers 36, busbar 44a, and supplemental busbar pads 44b disposed over the fingers 36 and busbar 44a. The fingers 36 and busbar 44a may be separate of unitary. The fingers 36 and busbar 44a may comprise the same majority metal, e.g. Ag, or be different than each other. The busbar pads 44b can comprise Cu or another metal, e.g. when formed from the invention composition. By utilizing the busbar pads 44b, the size of the busbar 44a (e.g. Ag busbar) can be reduced.

The PV cell 20 of FIG. 13 is similar to that of FIGS. 10 and 12, but includes a pair of busbars 44a and a supplemental busbar 44b disposed over the busbars 44a. The fingers 36 and busbars 44a can be separate or unitary. The fingers 36 and busbar 44a may comprise the same majority metal, e.g. Ag, or be different than each other. The supplemental busbar 44b can comprise Cu or another metal. By utilizing the supplemental busbar 44b, the size of the busbars 44a can be reduced.

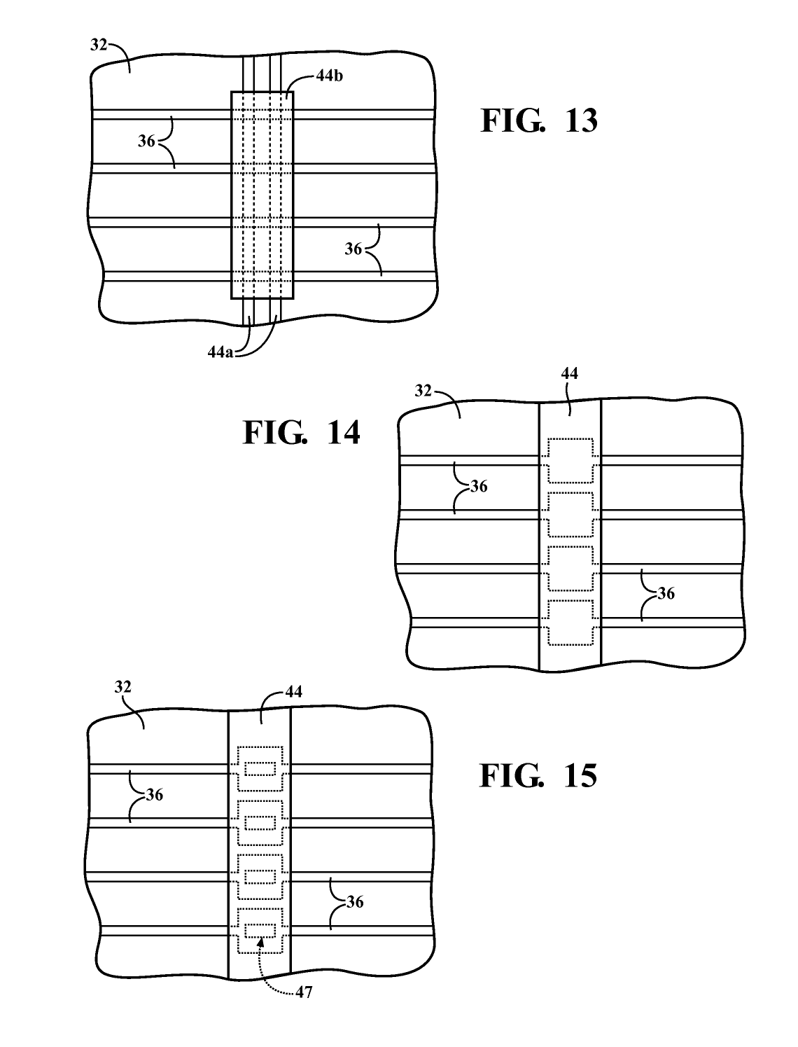

The PV cells 20 of FIGS. 14 and 15 are similar to that of FIG. 10, but include fingers 36 having pads in place of the gaps 47. The padded fingers 36 can help to improve electrical contact to the busbar 44, adhesion, while reducing the amount of Ag used and reducing manufacturing cost. The fingers 36 of FIG. 15 have hollow pads, i.e., internal gaps 47, which can reduce cost of manufacture and positively impact adhesion. A portion of the busbar 44 may be disposed in the gaps 47 of the hollow padded fingers 36.

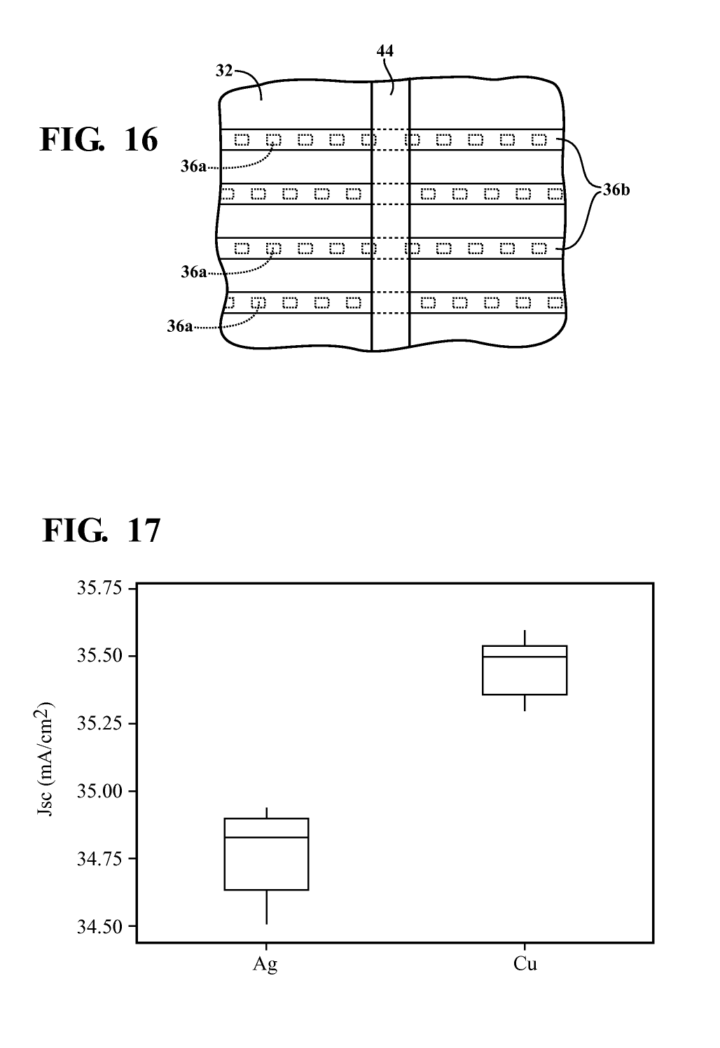

The PV cell 20 of FIG. 16 is similar to that of FIG. 10, but includes discontinuous-fingers 36a with supplemental fingers 36b disposed thereon. The discontinuous-fingers 36a can be in various shapes, such as rectangles, squares, dots, or combinations thereof. Such fingers 36a can be plated, printed, or formed in another manner. A plurality of gaps 47 are defined by the discontinuous-fingers 36a. The supplemental fingers 36b and the busbar 44 may be separate or unitary. By utilizing the discontinuous-fingers 36a and supplemental fingers 36b, cost of manufacture can be reduced. The discontinuous-fingers 36a typically contact the emitter 26 while the supplemental fingers 36b and busbar 44 carry current.

The present invention also provides a method of forming the PV cell 20. The method includes the step of applying a composition to the upper portions 40 of the fingers 36 to form a layer 44″. As used herein, a quotation mark (″) generally indicates a different state of the respective component, such as prior to curing, prior to sintering, etc. The composition can be applied by various methods, as alluded to above. In certain embodiments, the composition is printed on at least a portion of the upper portions 40 of the fingers 36 to form a layer 44″. Various types of deposition methods can be utilized, such as printing through screen or stencil, or other methods such as aerosol, ink jet, gravure, or flexographic, printing. In certain embodiments, the composition is screen printed directly onto portions of the coating layer 32 and the upper portions 40 of the fingers 36.

As shown in FIGS. 6 and 7, the upper doped region 26 of the base substrate 22 is free of (direct) physical contact with the layer 44″. The composition can be applied to the coating layer 32 and around each of the fingers 36 to make direct physical and electrical contact to the upper portions 40 of the fingers 36 with the layer 44″.

As alluded to above, the composition used to form the layer 44″ (eventually the busbar 44) comprises the second metal present in the composition in a majority amount. Such amounts are as described above. Typically, the second metal is Cu. The composition also comprises the third metal. Typically, the third metal is solder, e.g. Sn63Pb37. The composition is generally free of components capable of etching into the cover layer, e.g. fritted glass, such that the cover sheet is not etched by the composition.

Various types of Cu pastes can be used as the composition to form the layer 44″. In certain embodiments, the composition comprises a copper powder as the second metal, and a solder powder as the third metal. The solder powder melts at lower temperature than melting temperature of the copper powder. The composition further comprises a polymer, or a monomer which is polymerisable to yield a polymer. The polymer is generally a thermosetting resin, such as an epoxy, an acrylic, a silicone, a polyurethane, or combinations thereof. The composition can further comprise a cross-linking agent for the polymer and/or a catalyst for promoting cross-linking of the polymer. The cross-linking agent can be selected from carboxylated polymers, dimer fatty acids and trimer fatty acids. The composition may also include a solvent to adjust rheology. Other additives can also be included, such as dicarboxylic and/or monocarboxylic acids, adhesion promoters, defoamers, fillers, etc. Further examples of suitable Cu pastes, and components thereof, useful as the composition are disclosed in U.S. Pat. No. 7,022,266 to Craig, and in U.S. Pat. No. 6,971,163 to Craig et al., both of which are incorporated herein by reference in their entirety to the extent they do not conflict with the general scope of the invention.

The method further comprises the step of heating the layer 44″ to a temperature of no greater than about 300° C. to form the busbar 44. Heating is indicated in FIGS. 6 and 7 by wavy vertical lines. The layer 44″ is generally heated to a temperature of from about 150 to about 300, about 175 to about 275, about 200 to about 250, or about 225, ° C. In certain embodiments, the layer 44″ is heated at about 250° C. or less to form the busbar 44. Such temperatures generally sinter the third metal (e.g. solder) in the layer 44″, but do not sinter the second metal (e.g. Cu) in the layer 44″ to form the busbar 44. Such heating may also be referred to in the art as reflow or sintering.

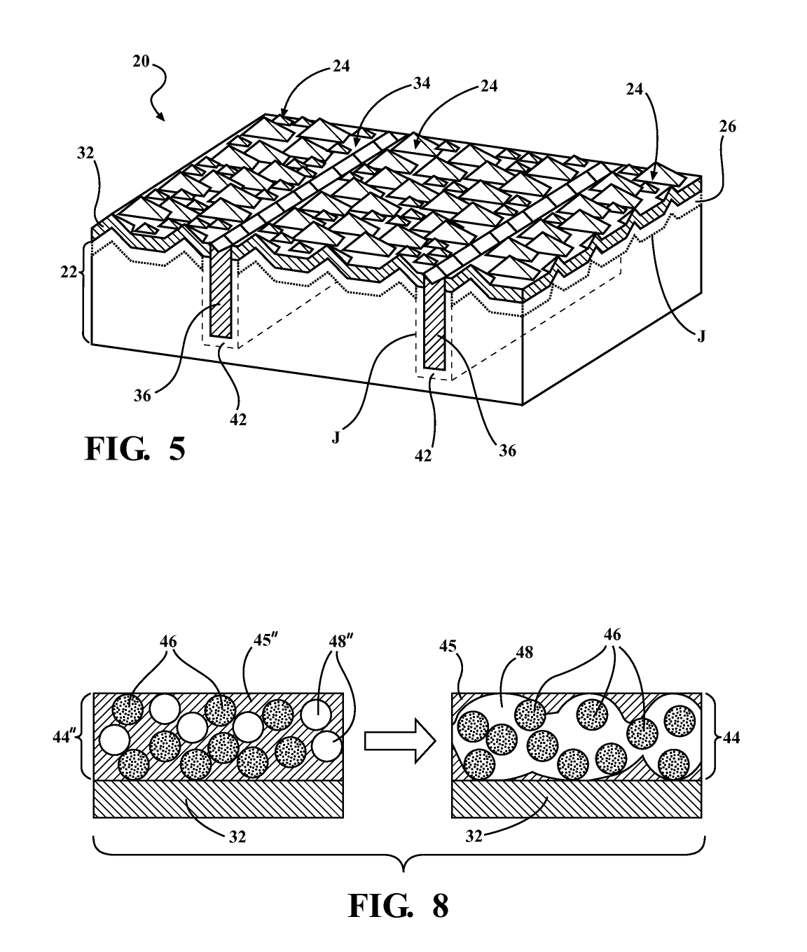

Referring to FIG. 8, it is believed that the particles of solder 48″ sinter and coat particles of Cu 46 during heating of the layer 44″ to form the busbar 44. Also during this time, the polymer 45″ can lose volatiles and crosslinks to a final cured state 45. Such coating enables the solder coated Cu 46 to carry current of the PV cell 20, and can also prevent oxidation of the Cu 46. Due to the lower temperatures, the Cu 46 does not generally sinter during the heating, based on it having a melting temperature of about 1000° C. The low temperature of this heating step generally allows for the use of temperature sensitive base substrates 22, e.g. amorphous silicon.

The layer 44″ can be heated for various amounts of time to form the busbar 44. Typically, the layer 44″ is heated only for the period of time required for the busbar 44 to form. Such times can be determined via routine experimentation. An inert gas, e.g. a nitrogen (N₂) gas blanket, can be used to prevent premature oxidation of the Cu 46 prior to being coated with the solder 48″. Unnecessarily overheating the busbar 44 for longer periods of time may damage the upper doped region 26 or other components of the PV cell 20 including the busbar 44.

Referring to FIG. 6, in one embodiment, prior to forming the busbar 44, the method comprises the step of applying a coating composition to the upper doped region 26 of the base substrate 22 to form the coating layer 32. The coating composition can comprise various components, such as those suitable for forming the coating layers 32 described above. The coating composition can be applied by various methods, as introduced above. For example, a PECVD process can be utilized. In embodiments where the coating layer 32 comprises SiN_{X}, silane, ammonia, and/or other precursors can be used in a PECVD furnace to form the coating layer 32.

The method further comprises the step of applying a metallic composition to portions of the coating layer 32 in a finger pattern corresponding to the fingers 36 to be formed. As shown in FIG. 6, each of the finger patterns 36″ has their lower portion 38″ in contact with the coating layer 32 and their upper portion 40″ spaced from the coating layer 32 after application. The metallic composition can be applied by various methods, as alluded to above. In certain embodiments, the metallic composition is printed on portions of the coating layer 32 to form the finger patterns 36″. Various types of printing methods can be utilized, such as screen, stencil, aerosol, ink jet, gravure, or flexographic, printing. In certain embodiments, the metallic composition is screen printed directly onto the coating layer 32 to form the finger patterns 36″. In other embodiments, the metallic composition is electrochemically deposited on portions of the coating layer 32 to form the finger patterns 36″. Other suitable methods are described above.

The metallic composition comprises the first metal present in the metallic composition in a majority amount. Such amounts are as described above. Typically, the first metal is Ag. The metallic composition typically includes one or more components for etching into the coating layer 32. Such components generally include fritted leaded glass. Other components may also be used in addition or alternate to leaded glass, such as unleaded or low leaded glass.

Various types of fritted Ag pastes can be used as the metallic composition. Such pastes generally include an organic carrier. Upon high temperature processing or “firing”, the organic carrier burns out and is removed from the bulk composition. Ag particles are dispersed throughout the carrier. A solvent may be included to adjust rheology of the paste. The fritted paste includes glass frits, which generally comprises PbO, B₂O₃, and SiO₂. The method is not limited to any particular fritted Ag paste, provided the paste can etch through the cover sheet at elevated temperatures, as described below. Examples of suitable fritted Ag pastes are commercially available from Ferro of Mayfield Heights, Ohio and Heraeus Materials Technology, LLC of West Conshohocken, Pa.

The method further comprises the step of heating the finger patterns 36″ to form the fingers 36. The finger patterns 36″ are generally heated to a temperature of from about 250 to about 1000, from about 500 to about 900, or about 720, ° C. Such temperatures generally sinter the first metal in the finger patterns 36″ to form the fingers 36. This heating step is generally much higher in temperature relative to the heating step used to form the busbar 44. In addition, the glass frit allows for the finger patterns 36″ to etch through the coating layer 32 and upon cooling, phase separate. This allows for direct electrical contact of the fingers 36 to the upper doped region 26 of the base substrate 22. Such heating may also be referred to in the art as firing.

The finger patterns 36″ can be heated for various amounts of time to etch through the coating layer 32. Typically, the finger patterns 36″ are heated only for the period of time required for the fingers 36 to uniformly contact the upper doped region 26. Such times can be determined via routine experimentation. Unnecessarily overheating the fingers 36 for longer periods of time may damage the upper doped region 26 or other components of the PV cell 20. After heating the finger patterns 36″ such that they can etch through the coating layer 32, the method further comprises the step of applying a composition to at least a portion of the upper portions 40 of the fingers 36 to form the layer 44″ as described above.

Referring to FIG. 7, in another embodiment, the fingers 44 are formed in a different manner than as described in the embodiment above. The coating layer 32 can be formed as described above. After forming the coating layer 32, holes 52 are formed therein. The holes 52 can be formed by various methods, such as by laser ablation, chemical etching, physical etching, etc. Such etching is different from the finger 36 “etching” described above. The fingers 36 are then formed in the holes 52. These fingers 36 are generally the plated fingers 36 as described above. The fingers 36 can be formed by depositing various metals into the holes 52. Various processes can be used, and different processes can be used for each layer of the fingers 36. An electrochemical plating process may be used to form the layers in the holes 52. Typically, such processes do not require a separate heating/firing step as described above. After forming the fingers 36, the method further comprises the step of applying a composition to at least a portion of the upper portions 40 of the fingers 36 to form the layer 44″ as described above.

The busbar 44 is directly solderable, which is useful for tabbing multiple PV cells 20 together, such as by attaching ribbons or interconnects to the busbars 44 of the PV cells 20. Said another way, typically there is no topcoat, protective, or outermost layer which needs to be removed from the busbar 44 prior to soldering directly thereto. This provides for reduced manufacturing time, complexity, and cost. For example, tabbing 50 can be directly soldered to the busbar 44 without the need for additional steps to be taken. In certain embodiments, an exception to this may be an additional fluxing step. In general, a surface is directly solderable if solder can be wet out on the surface after processing. For example, if one can either directly solder a wire to a substrate (within a commercially reasonable time frame and typically using an applied flux), use a tinned soldering iron to place a solder layer on the busbar, or simply heat up the substrate and see the solder wet out the electrode surface, the material would be directly solderable. In the case of a non-solderable system, even after applying flux and extensive heating, the solder never wets the surface, and no solder joint can be made. By using the busbar 44 and tabbing, it is possible to collect current from the fingers 36 effectively. As introduced above, the PV cell 20 may be used in various applications.

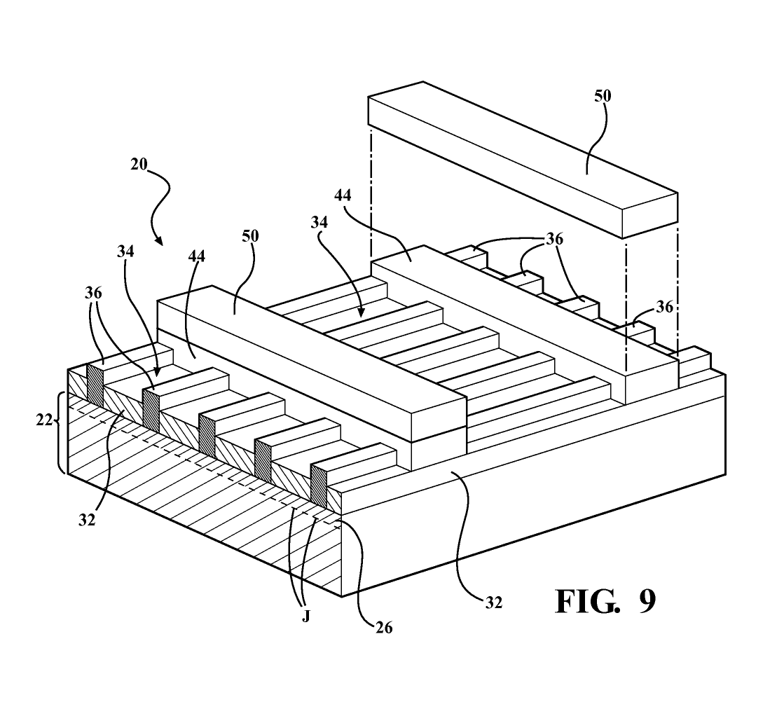

Referring to FIG. 9, tabbing 50 is disposed on the busbars 44. In certain embodiments, the tabbing 50 is directly solderable to the busbars 44 of the PV cells 20. In other embodiments, additional solder (not shown) may be used between the busbars 44 and tabbing 50. Fluxing means may be used to aid in soldering, such a flux pen or flux bed. The tabbing 50 itself may also include flux, such as Sn or Sn alloys and flux. The tabbing 50 can be formed from various materials, such as Cu, Sn, etc. Such tabbing 50 can be used to connect a series of PV cells 20. For example, a PV cell module (not shown) can include a plurality of the PV cells 20. Tabbing 50, e.g. ribbon, is generally in physical contact with the busbars 44 of the PV cells 20 to electrically connect the PV cells 20 in series. The tabbing 50 may also be referred to in the art as an interconnection. The PV module may also include other components, such as tie layers, substrates, superstrates, and/or additional materials that provide strength and stability. In many applications, the PV cells 20 are encapsulated to provide additional protection from environmental factors such as wind and rain.

Further embodiments of various types of PV cells 20 utilizing the invention composition to form one or more structures/components, such as conductors, electrodes, and/or busbars formed from the invention composition, are described in co-pending PCT Application No. ______ (Attorney Docket No. DC11370 PSP1; 071038.01091), filed concurrently with the subject application, the disclosure of which is incorporated by reference in its entirety to the extent it does not conflict with the general scope of the present invention.

In the embodiments immediately above and in other embodiments described herein, the invention composition generally comprises: a metal powder; a solder powder which has a lower melting temperature than a melting temperature of the metal powder; a polymer; a carboxylated-polymer different from the polymer for fluxing the metal powder and cross-linking the polymer; a dicarboxylic acid for fluxing the metal powder; and a monocarboxylic acid for fluxing the metal powder. The composition can optionally further comprise additives, such as a solvent and/or an adhesion promoter.

The metal powder can comprise copper, and the solder powder can have a melting temperature of no greater than about 300° C. The solder powder can comprise at least one of a tin-bismuth (SnBi) alloy, a tin-silver (SnAg) alloy, or combinations thereof. In specific embodiments, the solder powder comprises at least one tin (Sn) alloy and no greater than 0.5 weight percent (wt %) of: mercury, cadmium, and/or chromium; and/or lead.

In various embodiments, the metal and solder powders are collectively present in an amount of from about 50 to about 95 wt %; the metal powder is present in an amount of from about 35 to about 85 wt %; and/or the solder powder is present in any amount of from about 25 to about 75 wt %; each based on the total weight of the composition.

The polymer can comprise an epoxy resin, and the carboxylated-polymer can comprise an acrylic polymer, such as a styrene-acrylic copolymer. In various embodiments, the polymer and the carboxylated-polymer are collectively present in an amount of from about 2.5 to about 10 wt %; the polymer is present in an amount of from about 0.5 to about 5 wt; and/or the carboxylated-polymer is present in an amount of from about 1 to about 7.5 wt %; each based on the total weight of the composition. In certain embodiments, the polymer and the carboxylated-polymer are in a weight ratio of from about 1:1 to about 1:3 (polymer:carboxylated-polymer).

The dicarboxylic acid can be dodecanedioic acid (DDDA) and the monocarboxylic acid can be neodecanoic acid. In various embodiments, the dicarboxylic acid present in an amount of from about 0.05 to about 1 wt %; and/or the monocarboxylic acid is present in an amount of from about 0.25 to about 1.25 wt %; each based on the total weight of the composition. Additional aspects of these compositions can be appreciated with reference to the co-pending application.

The following examples, illustrating the PV cell 20 and the method of the present invention are intended to illustrate and not to limit the invention. The amount and type of each component used to form the compositions is indicated in Tables 1 through 3 below with all values in wt % based on a total weight of the respective composition unless otherwise indicated.

TABLE 1

| Component | Example | | |
|---|---|---|---|
| (wt %) | 1 | 2 | 3 |
| Second Metal 1 | 12.80 | 23.45 | 40.25 |
| Second Metal 2 | 34.63 | 26.81 | — |
| Third Metal 1 | 17.27 | 16.23 | 21.00 |
| Third Metal 2 | 12.10 | — | 23.76 |
| Third Metal 3 | 11.31 | 23.75 | — |
| Polymer 1 | 1.71 | 1.72 | — |
| Polymer 2 | — | — | — |
| Polymer 3 | 3.60 | 3.64 | 3.64 |
| Polymer 4 | — | — | 6.95 |
| Additive 1 | 1.98 | — | — |
| Additive 2 | — | 0.28 | 0.28 |
| Additive 3 | 1.00 | — | — |
| Additive 4 | 1.80 | 1.82 | 1.82 |
| Additive 5 | — | 0.48 | 0.48 |
| Additive 6 | 1.80 | 1.82 | 1.82 |
| Total | 100 | 100 | 100 |

Second Metal 1 is copper powder, commercially available from Mitsui Mining & Smelting Co. of Japan.

Second Metal 2 is a conventional silver powder, commercially available from Ferro.

Third Metal 1 is a Sn42/Bi58 alloy, having a melting temperature of about 221° C., commercially available from Indium Corporation of America.

Third Metal 2 is a Sn63/Pb37 alloy, having a melting temperature of about 183° C.

Third Metal 3 is a Sn96.5/Ag3.5 alloy, having a melting temperature of about 221° C., commercially available from Indium Corporation of America.

Polymer 1 is a solid epoxy resin comprising the reaction product of epichlorohydrin and bisphenol A and having an epoxy equivalent weight (EEW) of 500-560 g/eq, commercially available from Dow Chemical of Midland, Mich.

Polymer 2 is a silicone commercially available from Dow Corning Corp. of Midland, Mich.

Polymer 3 is a low molecular weight styrene-acrylic copolymer having an acid value of about 238, on solids, commercially available from BASF Corp. of Florham Park, N.J.

Polymer 4 is a polyurethane resin commercially available from BASF Corp.

Additive 1 is a monoterpene alcohol, commercially available from Sigma Aldrich of Chicago, Ill.

Additive 2 is a styrene dibromide, commercially available from Sigma Aldrich.

Additive 3 is dodecanedioic acid, commercially available from Sigma Aldrich.

Additive 4 is propylene glycol, commercially available from Sigma Aldrich.

Additive 5 is neodecanoic acid, commercially available from Hexion Specialty Chemicals of Carpentersville, Ill.

Additive 6 is benzyl alcohol, commercially available from Sigma Aldrich.

Additive 7 is a titanate adhesion promoter, commercially available from Kenrich Petrochemicals Co.

Additive 8 is a silane adhesion promoter comprising 2-(3,4-epoxycyclohexyl) ethyltrimethoxysilane, commercially available from Dow Corning Corp.

Additive 9 is a butyl carbitol, commercially available from Dow Chemical.

TABLE 2

| | |
|---|---|
| Component | Example |

| (wt %) | 4 | 5 | 6 | 7 |
|---|---|---|---|---|
| Second Metal 1 | 46.45 | 47.72 | 46.5600 | 47.83 |
| Second Metal 2 | — | — | — | — |
| Third Metal 1 | — | 15.63 | 16.2283 | 20.55 |
| Third Metal 2 | 40.01 | — | — | 20.45 |
| Third Metal 3 | — | 24.38 | 23.7501 | — |
| Polymer 1 | 2.45 | 1.76 | 1.7243 | 1.71 |
| Polymer 2 | 5.50 | — | — | — |
| Polymer 3 | — | 3.72 | 3.6362 | 3.60 |
| Polymer 4 | — | — | — | — |
| Additive 1 | 1.98 | 2.05 | 2.0050 | 1.98 |
| Additive 2 | — | 0.29 | 0.2807 | 0.28 |
| Additive 3 | — | 0.25 | 0.2432 | — |
| Additive 4 | 1.80 | 1.86 | 1.8185 | 1.80 |
| Additive 5 | — | 0.50 | 0.4840 | — |
| Additive 6 | 1.80 | 1.86 | 1.8185 | 1.80 |
| Additive 7 | — | — | 0.5567 | — |
| Additive 8 | — | — | 0.3036 | — |
| Additive 9 | — | — | 0.5907 | — |
| Total | 100 | 100 | 100 | 100 |

TABLE 3

| Component | Example | | |
|---|---|---|---|
| (wt %) | 8 | 9 | 10 |
| Second Metal 1 | 47.72 | 46.45 | 12.80 |
| Second Metal 2 | — | — | 34.63 |
| Third Metal 1 | 15.63 | — | 17.27 |
| Third Metal 2 | — | 40.01 | 12.10 |
| Third Metal 3 | 24.38 | — | 11.31 |
| Polymer 1 | — | — | 1.71 |
| Polymer 2 | — | 7.95 | — |
| Polymer 3 | — | — | 3.60 |
| Polymer 4 | 5.48 | — | — |
| Additive 1 | 2.05 | 1.98 | 1.98 |
| Additive 2 | 0.29 | — | — |
| Additive 3 | 0.25 | — | 1.00 |
| Additive 4 | 1.86 | 1.80 | 1.80 |
| Additive 5 | 0.50 | — | — |
| Additive 6 | 1.86 | 1.80 | 1.80 |
| Total | 100 | 100 | 100 |

A series of 5 inch (12.7 cm) monocrystalline silicon cells (wafers) are prepared for application of Ag and Cu pastes. The pastes according to the Examples above are prepared. Each of the pastes is diluted down with 1 wt % butyl carbitol to improve print rheology. Each of the pastes is printed on the wafers to form Cu busbars via a busbar screen from Sefar, a stainless steel screen 325 or 165 mesh, with a 12.7 μm emulsion thickness (PEF2), and a 22° or 45° rotation of the mesh. Printing is performed with an AMI screen printer with a ˜0.68 kg down force, with a 200 μm blank wafer on the stage. Print speed is set to between 3-5 inch/sec in a print-print mode. The wafers are printed and put through a BTU Pyramax N₂ reflow oven.

Durability of the Cu busbars under damp heat (DH; 85° C., 85% relative humidity) aging conditions is determined. Unencapsulated prints of Cu busbars on silicon are used to monitor the Cu bulk resistivity (ρ). The quality of the tabbing/Cu busbars is also monitored using contact resistivity (ρ_{C}) utilizing the TLM method. With Example 5, after 1000 hours of exposure to DH, no degradation of the Cu busbars is seen relative to the Ag busbars.

Current-voltage (I-V) measurements using a flash tester (PSS 10 II) are performed. The Cu busbars according to Example 5 show increased V_{OC} and J_{SC} compared to the comparative Ag busbars. Specifically, cells including Cu busbars show a distinct improvement in V_{OC} and J_{SC}, relative to cells including Ag busbars. The increase generally corresponds to a 0.6% and 2.59% relative increase in V_{OC} and J_{SC}, respectively. It is believed that this increase is attributed to the reduction of metal/silicon contact area, as described above.

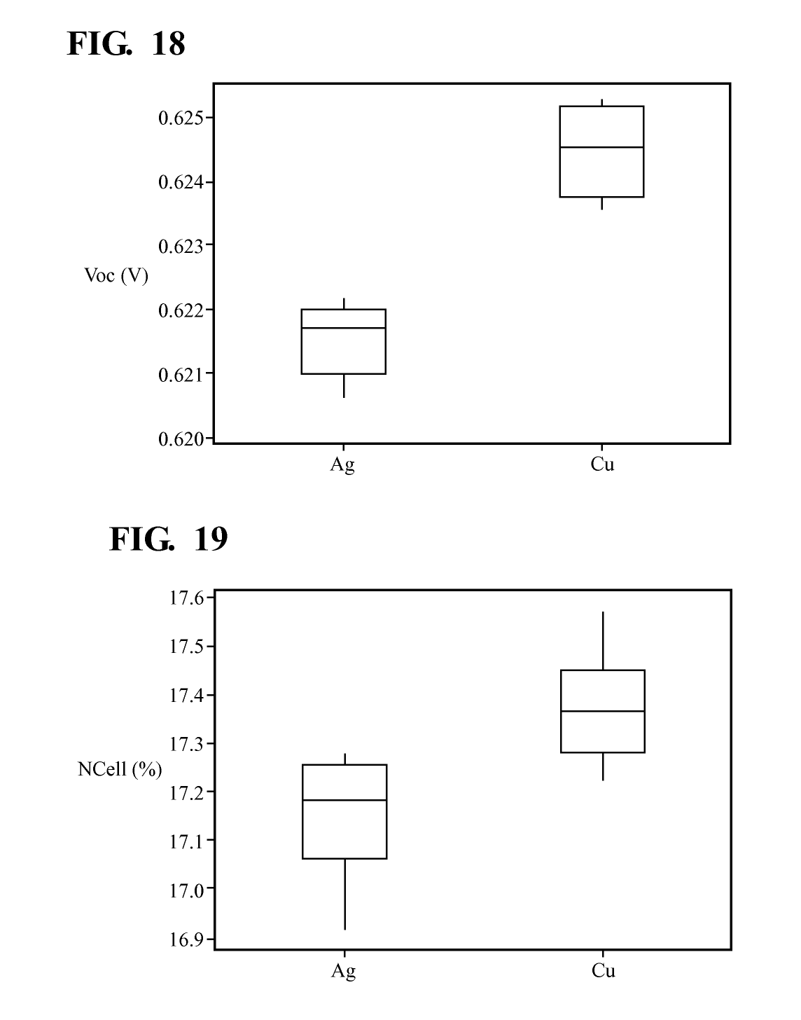

Another batch of screen printed Al BSF wafers is prepared with rear contact pads. The wafers include front Ag and front Cu prints all with rear Ag busbars. The Cu busbars are printed with the Cu paste according to Example 5 described above. The cells are tabbed manually and tested prior to encapsulation. The cells can be tabbed using typical industry tabbing. In these examples, tabbing can be performed by hand using a soldering iron at 390° C. and flux. Front grid resistance is measured, along with I-V, and Suns Voc to determine quality of the cells and the metallization. The measurement results are shown in FIGS. 17 through 19. The batch shows an improved V_{OC} and J_{SC}, again attributed to a decrease in metal/silicon contact area.

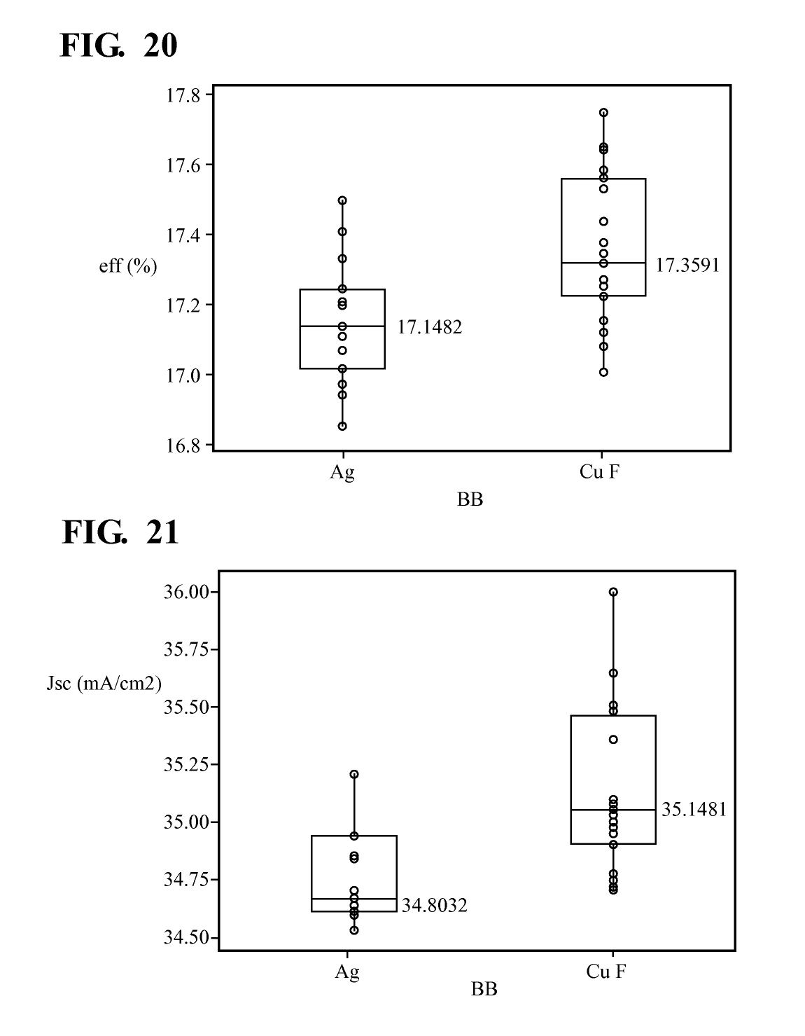

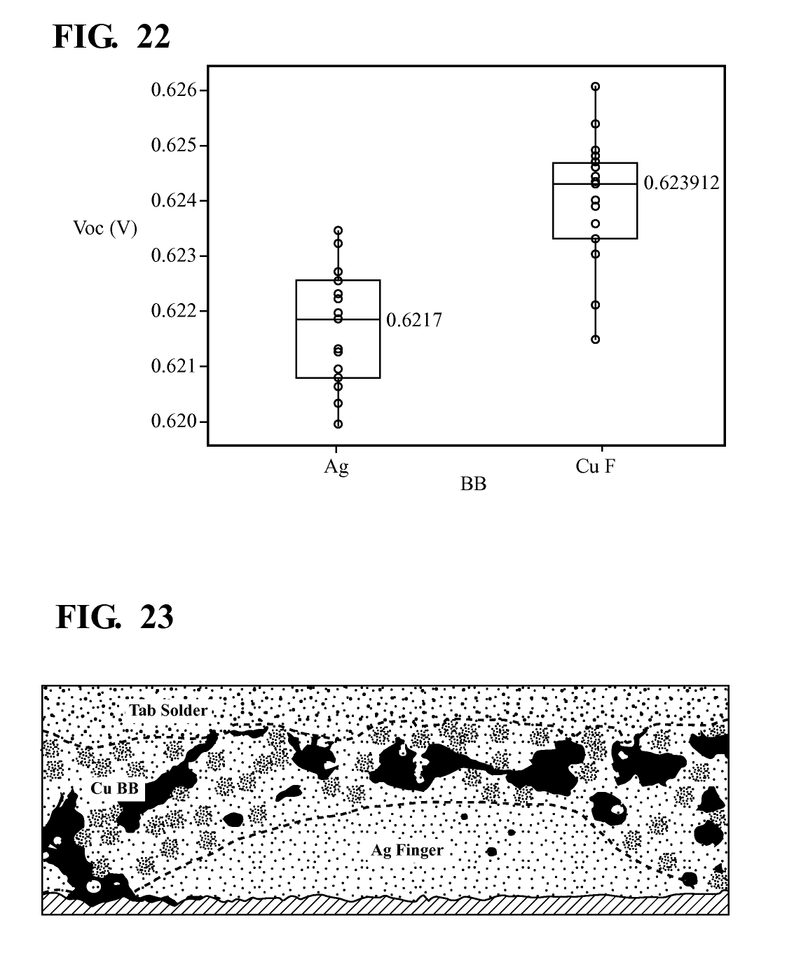

Referring to FIG. 20, a box graph illustrating efficiency percentage of the comparative and invention PV cells is depicted, whereas FIG. 21 illustrates J_{SC}, and FIG. 22 illustrates V_{OC} of the examples. Specifically, IV data for samples is measured. Ag examples are 149-1 through -15, and Cu F examples are 149-A through -S. Mean values are shown. The comparative and invention examples are the same as described above in the previous example Figures. From the data, it is clearly shown that the use of the Cu busbar of the present invention has a distinct improvement in cell performance. This improvement is believed to come from the reduced recombination by reducing the metal/silicon interface area with reduced high temperature fired Ag metallization points.

FIG. 23 is a cross-sectional optical microscopy photograph illustrating a tabbed busbar of the invention. Specifically, a Cu busbar is printed on top of a SiNx passivation layer and on top a Ag finger and later tabbed. Various components of the invention composition are shown in the cross-section. A direct solder bond to the tabbing/busbar and busbar/finger is shown, as well as the adhesive contact between the Cu busbar and the substrate.

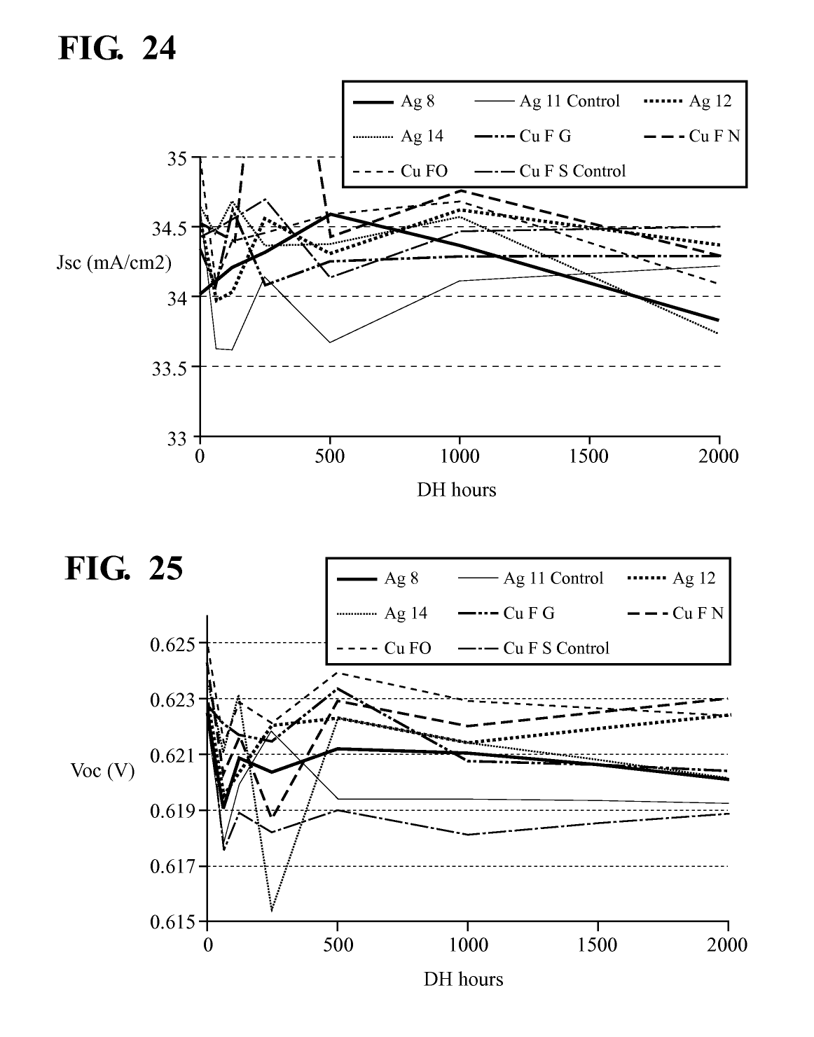

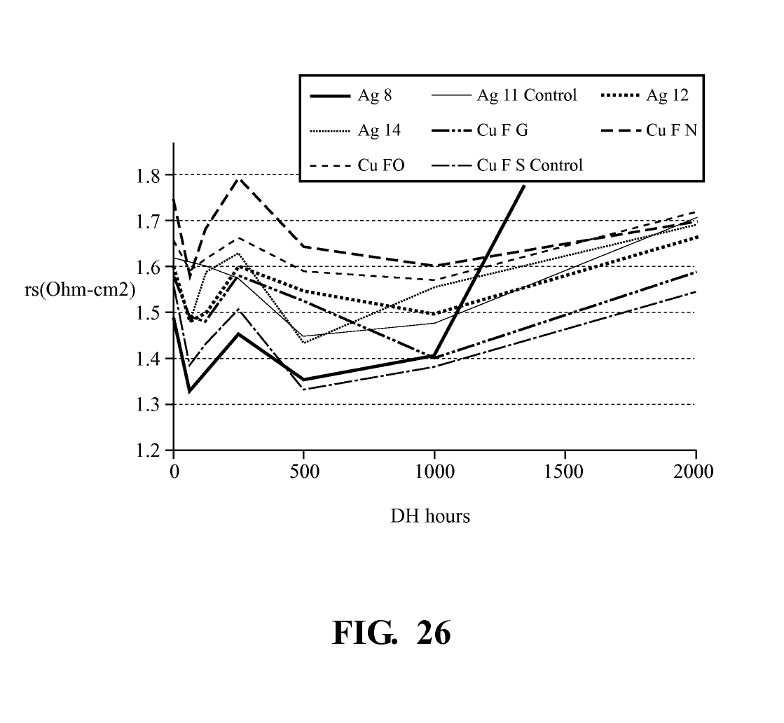

FIG. 24 is a line graph illustrating J_{SC} of comparative and invention PV cell examples after damp heat aging. FIG. 25 is a line graph illustrating V_{OC} of the comparative and invention PV cells after damp heat aging, and FIG. 26 is a line graph illustrating sheet resistivity (rs) of the comparative and invention PV cell examples after damp heat aging. From these graphs it is clear that the Cu paste is not degrading performance under corrosive conditions.

One or more of the values described above may vary by ±5%, ±10%, ±15%, ±20%, ±25%, etc. so long as the variance remains within the scope of the disclosure. Unexpected results may be obtained from each member of a Markush group independent from all other members. Each member may be relied upon individually and or in combination and provides adequate support for specific embodiments within the scope of the appended claims. The subject matter of all combinations of independent and dependent claims, both singly and multiply dependent, is herein expressly contemplated. The disclosure is illustrative including words of description rather than of limitation. Many modifications and variations of the present disclosure are possible in light of the above teachings, and the disclosure may be practiced otherwise than as specifically described herein.

1. A photovoltaic cell comprising:
a base substrate comprising silicon and including an upper doped region;
a coating layer disposed on said upper doped region of said base substrate and having an outer surface;
a plurality of fingers spaced from each other and disposed in said coating layer and each of said fingers having a lower portion in electrical contact with said upper doped region of said base substrate, and an upper portion opposite said lower portion extending outwardly through said outer surface of said coating layer, with each of said fingers comprising a first metal present in each of said fingers in a majority amount; and
a busbar spaced from said upper doped region of said base substrate such that said upper doped region of said base substrate is free of physical contact with said busbar, with said busbar in electrical contact with said upper portions of said fingers and comprising a second metal present in said busbar in a majority amount;
wherein said busbar further comprises a third metal different from said first metal of said fingers and said second metal of said busbar with said third metal having a melting temperature of no greater than about 300° C.; and
wherein said upper doped region of said base substrate is in electrical communication with said busbar via said fingers.

2. The photovoltaic cell as set forth in claim 1,
wherein said busbar is formed at a temperature of no greater than about 300° C. from a composition comprising said second metal and enabling said busbar to be formed at said temperature.

3. A photovoltaic cell comprising:
a base substrate comprising silicon and including an upper doped region;
a coating layer disposed on said upper doped region of said base substrate and having an outer surface;
a plurality of fingers disposed in said coating layer and each of said fingers having a lower portion in electrical contact with said upper doped region of said base substrate, and an upper portion opposite said lower portion extending outwardly through said outer surface of said coating layer, with each of said fingers comprising a first metal present in each of said fingers in a majority amount; and
a busbar spaced from said upper doped region of said base substrate such that said upper doped region of said base substrate is free of physical contact with said busbar, with said busbar in electrical contact with said upper portions of said fingers and comprising a second metal present in said busbar in a majority amount;
wherein said first metal of said fingers is different from said second metal of said busbar.

4. The photovoltaic cell as set forth in claim 1, wherein said base substrate further includes a lower doped region opposite said upper doped region.

5. The photovoltaic cell as set forth in claim 1, wherein said busbar is disposed on said outer surface of said coating layer and around each of said fingers to physically and electrically contact said upper portions of said fingers with said coating layer disposed between said busbar and said upper doped region of said base substrate.

6. The photovoltaic cell as set forth in claim 1, wherein said upper doped region of said base substrate is an n-type doped region or a p-type doped region.

7. The photovoltaic cell as set forth in claim 1, wherein said coating layer comprises SiO_{X}, ZnS, MgF_{X}, SiN_{X}, SiCN_{X}, AlO_{X}, TiO₂, a transparent conducting oxide (TCO), or combinations thereof.

8. The photovoltaic cell as set forth in claim 1, wherein said first metal of said fingers comprises silver or copper, said second metal of said busbar comprises copper or silver, alternatively copper, and said third metal of said busbar comprises solder.

9. The photovoltaic cell as set forth in claim 1, wherein:
said upper doped region is selected from an n-type doped region or a p-type doped region; said base substrate further comprises
a lower doped region opposite said upper doped region;
said coating layer comprises SiO_{X}, ZnS, MgF_{X}, SiN_{X}, SiCN_{X}, AlO_{X}, TiO₂, a transparent conducting oxide (TCO), or combinations thereof;
each of said fingers comprises silver or copper present in each of said fingers in a majority amount; and
said busbar comprises copper in a majority amount and solder.

10. The photovoltaic cell as set forth in claim 1, wherein said first metal of said fingers is silver and said second metal of said busbar is copper.

11. The photovoltaic cell as set forth in claim 1, wherein said solder comprises a tin alloy.

12. The photovoltaic cell as set forth in claim 1, wherein said busbar is formed from a composition comprising;
a copper powder as said second metal,
a solder powder which melts at lower temperature than said copper powder as said third metal, and
a polymer.

13. The photovoltaic cell as set forth in claim 1, wherein said busbar is directly solderable.

14. The photovoltaic cell as set forth in claim 1, further comprising a plurality of supplemental fingers disposed over and in electrical contact with said plurality of fingers, with each of said supplemental fingers comprising silver or copper present in each of said supplemental fingers in a majority amount, and wherein said supplemental fingers are different from said plurality of fingers.

15. The photovoltaic cell as set forth in claim 1, further comprising a supplemental busbar disposed over and in electrical contact with said busbar, and wherein said supplemental busbar is different from said busbar.

16. A photovoltaic cell module comprising a plurality of said photovoltaic cells as set forth in claim 1, and further comprising at least one ribbon in physical contact with said busbars of said photovoltaic cells such that said photovoltaic cells are in electrical communication with each other via said ribbon.

17. A method of forming a photovoltaic cell comprising a base substrate comprising silicon and including an upper doped region, a coating layer disposed on the upper doped region, a plurality of fingers spaced from each other and disposed in the coating layer and in electrical contact with the upper doped region of the base substrate and comprising a first metal present in each of the fingers in a majority amount, and a busbar spaced from the upper doped region and in electrical contact with the fingers, said method comprising the steps of:
applying a composition comprising a second metal present in the composition in a majority amount and a third metal to at least a portion of the upper portions of the fingers to form a layer such that the upper doped region of the base substrate is free of physical contact with the layer; and
heating the layer to a temperature of no greater than about 300° C. to form the busbar;
wherein the third metal of the busbar is different from the first metal of the fingers and the second metal of the composition; and
wherein the upper doped region of the base substrate is in electrical communication with the busbar via the fingers.

18. The method as set forth in claim 17, wherein the first metal of the fingers comprises silver or copper, the second metal of the composition comprises copper or silver, alternatively copper, and the third metal of the composition comprises solder.

19. The method as set forth in claim 17, wherein applying the composition is further defined as printing the composition on the upper portions of the fingers to define the busbar.

20. The method as set forth in claim 17, wherein the composition comprises;
a copper powder as the second metal,
a solder powder which melts at lower temperature than melting temperature of the copper powder, as the third metal, and
a polymer.
